(19) United States
(12) Patent Application Publication
(10) Pub. No.: US 2024/0284663 A1
(43) Pub. Date: Aug. 22, 2024

(54) ASYMMETRIC TRANSISTOR DEVICES

(71) Applicant: Micron Technology, Inc., Boise, ID (US)

(72) Inventors: Srinivas Pulugurtha, Boise, ID (US); Dan Mihai Mocuta, Boise, ID (US)

(21) Appl. No.: 18/440,348

(22) Filed: Feb. 13, 2024

Related U.S. Application Data
(60) Provisional application No. 63/446,655, filed on Feb. 17, 2023.

(51) Int. Cl. H10B 12/00; G11C 11/4091

(52) U.S. Cl. CPC H10B 12/50; G11C 11/4091

(57) ABSTRACT

A variety of applications can include an apparatus having one or more pairs of transistors sharing a common source region that provide asymmetric transistor devices. The drains of the transistors of a pair sharing a common source region can be structured with the source junction depth being shallower than the drain junction depth of the drain region of at least one of the transistors of the pair. Tilted implantation can be used to extend a drain junction depth beyond the distance of the source junction depth by implanting additional dopants. The extension of the drain junction depth can be accomplished without additional masks being used in processing to dope only a drain region and skip doping on a corresponding source region.

### PRIORITY APPLICATION

This application claims the benefit of priority to U.S. Provisional Application Ser. No. 63/446,655, filed 17 Feb. 2023, which is incorporated herein by reference in its entirety.

### FIELD OF THE DISCLOSURE

Embodiments of the disclosure relate generally to integrated circuits, and more specifically, to devices having asymmetric transistor devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, transistors in an integrated circuit for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a device having components of two transistors in a substrate, with the two transistors sharing a common source region, according to various embodiments.

FIG. 2 illustrates a device having two transistors, with the two transistors sharing a common source region, along with other transistors in a substrate, according to various embodiments.

FIG. 3 shows a structure after several processing stages to form a device having two transistors sharing a common source region, according to various embodiments.

FIG. 4 illustrates a structure after further processing the structure of FIG. 3, according to various embodiments.

FIG. 5 is a flow diagram of features of an example method of forming an electronic device, according to various embodiments.

FIG. 6 is a schematic of an embodiment of an example dynamic random-access memory device that can include an architecture having a memory array region and periphery circuits to the memory array, in which the periphery circuits can have asymmetric transistor devices, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In electronic devices having transistors that share a common source junction, the common source junction can be affected by the available space in the doping of source and drain regions during the fabrication of the transistors. For example, in fabricating a n-type sense amplifier (NSA) and in fabricating a p-type sense amplifier (PSA), there are multiple pairs of transistors having common source junctions that are affected by the available space for dopant implant, which can result in reduced drain-to-source current (I_{DS}) for the device. This problem can be aggravated with each shrinkage in technology. The available options to improve the common junction of such transistors and I_{DS} have trade-off with other devices of the integrated circuit (IC) or use an additional processing mask.

In various embodiments, an asymmetric junction can be implemented that is the structuring of the drain junctions deeper than the source junction of transistors that share a common source region. Such an asymmetric junction scheme can be used to control the threshold voltage (Vₜ) of the device through the source side of transistors that share the common source region. After lightly doped drain (LDD) implants or Halo dopant implants have been introduced to the common source region and to the drains of transistors sharing the common source region, an additional tilted implant of suitable dose and energy can be done. A halo region is a doped region with implants to reduce a short channel effect, which can occur when the transistor channel length is on the same order of magnitude as the depletion-layer widths of the source junction and the drain junction. The tilt angle for the additional tilted implant can be selected such that the implant of additional dopants is blocked in the tight space for the source region. While the drain junctions of the two transistors sharing the common source region received additional dopant dose to make the drain junctions deeper, the blocking of implanting dopants in the source region substantially maintains the source junction of the common source region. With the drains having deeper drain junctions than the source junction of the common source region, an asymmetric junction is defined for the two transistors having the common source region. In addition, the Vₜ of the device, having the two transistors sharing the common source region, can be set by the energy barrier on the source side, with no tilt halo implant. For matched Vₜ of the two transistors, the implant scheme to block dopant implant in the common source region can improve the on-state transistor current (I_{ON}) by about 3% to about 5%.

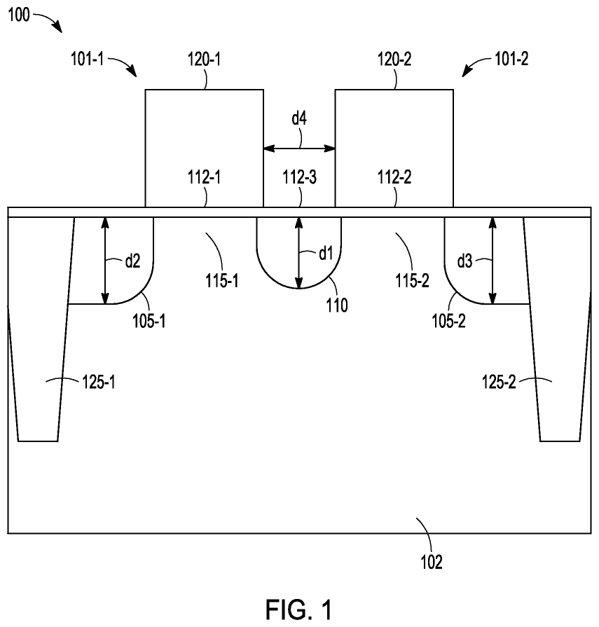

FIG. 1 illustrates a device 100 having components of two transistors 101-1 and 101-2 in a substrate 102, with transistors 101-1 and 101-2 sharing a common source region 110. Transistor 101-1 includes a drain region 105-1 separated from source region 110 by a channel structure 115-1, where channel structure 115-1 is separated from a gate structure 120-1 of transistor 101-1 by a dielectric 112-1. Transistor 101-2 includes a drain region 105-2 separated from source region 110 by a channel structure 115-2, where channel structure 115-2 is separated from a gate structure 120-2 of transistor 101-2 by a dielectric 112-2. A dielectric 112-3 can be located on source region 110. Insulating regions, disposed over these components and other components of device 100, are not known for case of discussion of the characteristics of the active areas of transistors 101-1 and 101-2.

Transistors 101-1 and 101-2 can be n-type metal-oxide-semiconductor field-effect (NMOS) transistors. With transistors 101-1 and 101-2 being NMOS transistors, source region 110 and drain regions 105-1 and 105-2 are n-type regions and substrate 102 is a p-type substrate for transistors 101-1 and 101-2. Alternatively, transistors 101-1 and 101-2 can be p-type metal-oxide-semiconductor field-effect (PMOS) transistors. With transistors 101-1 and 101-2 being PMOS transistors, source region 110 and drain regions 105-1 and 105-2 are p-type regions and substrate 102 can be a n-type substrate for transistors 101-1 and 101-2. Substrate 102 being a substrate for transistors 101-1 and 101-2, substrate 102 can be a well of one type of conductivity in a larger substrate. Device 100 can be, but is not limited to, a silicon-based device, at least for the active regions of transistor 101-1, transistor 101-2, and other similar transistors of device 100. Other material technologies can be used.

Dielectric 112-1, providing a tunnel region of transistor 101-1 with respect to gate structure 120-1 and channel structure 115-1, can be an oxide, a combination of dielectric regions, or other appropriate dielectric material. The dielectric oxide can be a silicon oxide or a high-k oxide, where a high-k oxide is a dielectric oxide having a dielectric constant greater than that of silicon dioxide. The combination of dielectric regions can include a silicon oxide and a dielectric nitride such as, but not limited to, a silicon nitride. Dielectric 112-2, providing a tunnel region of transistor 101-2 with respect to gate structure 120-2 and channel structure 115-2, can be an oxide, a combination of dielectric regions, or other appropriate dielectric material. The dielectric oxide can be a silicon oxide or a high-k oxide. The combination of dielectric regions can include a silicon oxide and a dielectric nitride such as, but not limited to, a silicon nitride. Dielectric 115-3, disposed on source region 110 between gate structure 120-1 and gate structure 120-2, can be an oxide, a combination of dielectric regions, or other appropriate dielectric material. The dielectric oxide can be a silicon oxide or a high-k oxide. The combination of dielectric regions can include a silicon oxide and a dielectric nitride such as, but not limited to, a silicon nitride. Dielectric 112-1 can have the same composition as dielectric 112-2. Dielectric 112-3 can have the same composition as dielectric 112-1 or dielectric 112-2.

Gate structure 120-1 of transistor 101-1 is a conductive structure, which can comprise a single conductive material or multiple conductive material regions. Gate structure 120-1 can be a conductive polysilicon gate, a metal gate, a metal gate separated from dielectric 112-1 by one or more metal barrier regions, or, in combination with dielectric 112-1, a high-k metal gate (HKMG). A HKMG is a gate comprising a metal composition located on a high-k dielectric. The high-k dielectric of the HKMG can be located on a thin layer of silicon oxide. Material for the metal gate of gate structure 120-1 can be, but is not limited to, tungsten or ruthenium. Metal barrier regions can include, but are not limited to, one or more of tungsten silicide, tungsten nitride, titanium, titanium nitride, or titanium silicide. Other conductive materials can be used for gate structure 120-1. Gate structure 120-2 of transistor 101-2 is a conductive structure, which can comprise a single conductive material or multiple conductive material regions. Gate structure 120-2 can be a conductive polysilicon gate, a metal gate, a metal gate separated from dielectric 112-2 by one or more metal barrier regions, or, in combination with dielectric 112-2, a HKMG. The high-k dielectric of the HKMG can be located on a thin region of silicon oxide. Material for the metal gate of gate structure 120-2 can be, but is not limited to, tungsten or ruthenium. Metal barrier regions can include, but are not limited to, one or more of tungsten silicide, tungsten nitride, titanium, titanium nitride, or titanium silicide. Other conductive materials can be used for gate structure 120-2. The composition of gate structure 120-2 can be the same as the composition of gate structure 120-1.

Source region 110 has a source junction having a source junction depth of d1 from the top of source region 110 to the bottom of source region 110. Drain region 105-1 has a drain junction having a drain junction depth of d2 from the top of drain region 105-1 to the bottom of drain region 105-2. Drain region 105-2 has a drain junction having a drain junction depth of d3 from the top of drain region 105-2 to the bottom of drain region 105-2. Source junction depth d1 can be shallower than drain junction depth d2 and shallower than drain junction depth d3. By shallower, it is meant that source junction depth d1 is less than drain junction depth d2 by more than a tolerance specification for transistor 101-1 and that source junction depth d1 is less than drain junction depth d3 by more than a tolerance specification for transistor 101-2. In a typical transistor structure, the source junction depth and the drain junction depth are substantially the same. In device 100, with source junction depth d1 being shallower than drain junction depth d2 or shallower than drain junction depth d3, device 100 defines an asymmetric device. Drain junction depth d2 or drain junction depth d3 can be at least twice source junction depth d1. Drain junction depth d2 can be equal to drain junction depth d3 within tolerance specifications for transistors 101-1 and 101-2.

Construction of source region 110 having a shallower source junction depth than the drain junction depth of transistor 101-1 or transistor 101-2 can be based on doping procedures for transistors 101-1 and 101-2. With standard processing, source and drain regions are doped in the same procedural stage, resulting in source junction and drain junction depths having the same depth (within process tolerance). Transistor 101-1 and transistor 101-2 can be constructed as an asymmetric device by additional doping of drain region 105-1 and drain region 105-2 while inhibiting or preventing additional doping of common source region 110, extending the drain junctions of drain region 105-1 and drain region 105-1 to depths larger than the source junction of source region 110. Arrangement of gate structure 120-1 relative to gate structure 120-2 can be used to inhibit or prevent additional doping of common source region 110. For a distance d4 of an opening between gate structure 120-1 relative to gate structure 120-2 during processing of transistors 101-1 and 101-2, the opening defined by d4 can be used in the inhibiting or preventing of additional doping of source region 110. The selective additional doping of drain region 105-1 and drain region 105-2 relative to common source region 110 can be a function of distance d4 between gate structure 120-1 and gate structure 120-1 over the common source region 110.

The distance d4 may be further defined by dielectric sidewalls on gate structures 120-1 and 120-2, which sidewalls are not shown in FIG. 1. In various embodiments, the transistors of device 100 can include LDDs and Halo regions. Device 100 can also include shallow trench isolation (STI) regions 125-1 and 125-2, which are regions to isolate active electrical components of an IC. STI region 125-1 can isolate drain region 105-1 of transistor 101-1 from other conductive components of device 100 such as, but not limited to, other transistors of device 100. STI region 125-2 can isolate drain region 105-2 of transistor 101-2 from other conductive components of device 100 such as, but not limited to, other transistors of device 100.

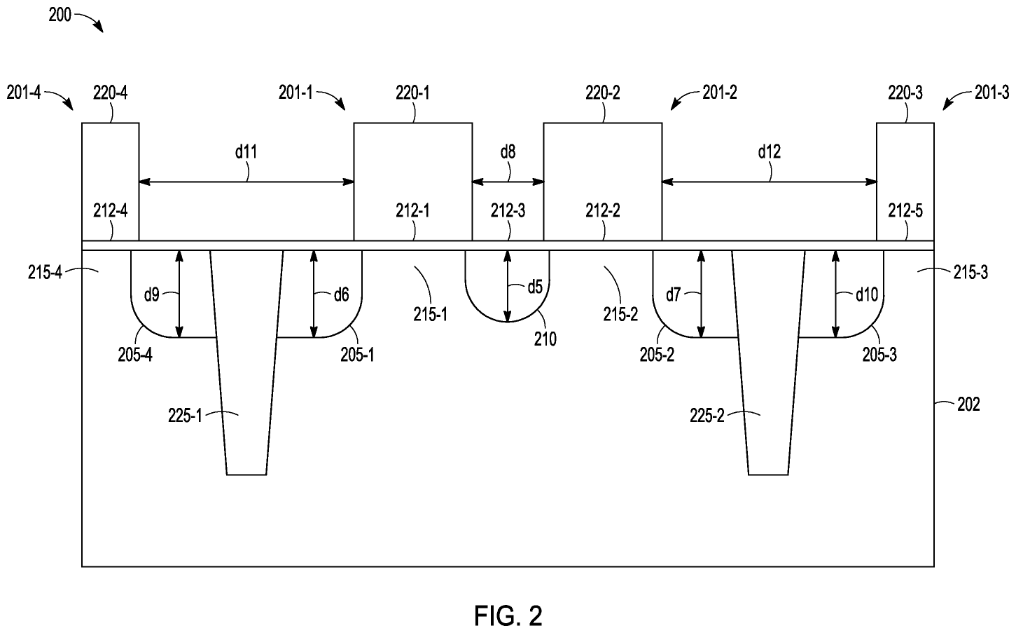

FIG. 2 illustrates a device 200 having transistors 201-1 and 201-2 in a substrate 202 along with other transistors. Similar to device 100 of FIG. 1, device 200 shares a common source region 210. Transistor 201-1 includes a drain region 205-1 separated from source region 210 by a channel structure 215-1, where channel structure 215-1 is separated from a gate structure 220-1 of transistor 201-1 by a dielectric 212-1. Transistor 201-2 includes a drain region 205-2 separated from source region 210 by a channel structure 215-2, where channel structure 215-2 is separated from a gate structure 220-2 of transistor 201-2 by a dielectric 212-2. A dielectric 212-3 can be located on source region 210. A STI region 225-1 can isolate drain region 205-1 of transistor 201-1 from a transistor 201-4 having a drain region 205-4 and a channel structure 215-4 separated from a gate structure 220-4 by a dielectric 212-4. A STI region 225-2 can isolate drain region 205-2 of transistor 201-2 from a transistor 201-3 having a drain region 205-3 and a channel structure 215-3 separated from a gate structure 220-3 by a dielectric 212-5. Only active area portions of transistors 201-3 and 201-4 are not shown. Device 200 can include multiple pairs of transistors sharing a common source region, similar to transistors 201-1 and 201-2, depending on the architecture and function of device 200. Insulating regions, disposed over these components and other components of device 200, are not shown for case of discussion of the characteristics of the active areas of transistors 201-1 and 201-2.

Transistors 201-1 and 201-2 can be NMOS transistors. With transistors 201-1 and 201-2 being NMOS transistors, source region 210 and drain regions 205-1 and 205-2 are n-type regions and substrate 202 is a p-type substrate for transistors 201-1 and 201-2. Alternatively, transistors 201-1 and 201-2 can be PMOS transistors. With transistors 201-1 and 201-2 being PMOS transistors, source region 210 and drain regions 205-1 and 205-2 are p-type regions and substrate 202 can be a n-type substrate for transistors 201-1 and 201-2. Substrate 202 being a substrate for transistors 201-1 and 201-2, substrate 202 can be a well of one type of conductivity in a larger substrate. Device 200 can be, but is not limited to, a silicon-based device, at least for the active regions of transistor 201-1, transistor 201-2, and other similar transistors of device 200. Other material technologies can be used.

Dielectric 212-1, providing a tunnel region of transistor 201-1 with respect to gate structure 220-1 and channel structure 215-1, can be an oxide, a combination of dielectric regions, or other appropriate dielectric material. The dielectric oxide can be a silicon oxide or a high-k oxide, where a high-k oxide is a dielectric oxide having a dielectric constant greater than that of silicon dioxide. The combination of dielectric regions can include a silicon oxide and a dielectric nitride such as, but not limited to, a silicon nitride. Dielectric 212-2, providing a tunnel region of transistor 201-2 with respect to gate structure 220-2 and channel structure 215-2, can be an oxide, a combination of dielectric regions, or other appropriate dielectric material. The dielectric oxide can be a silicon oxide or a high-k oxide. The combination of dielectric regions can include a silicon oxide and a dielectric nitride such as, but not limited to, a silicon nitride. Dielectric 212-3, disposed on source region 210 between gate structure 220-1 and gate structure 220-2, can be an oxide, a combination of dielectric regions, or other appropriate dielectric material. The dielectric oxide can be a silicon oxide or a high-k oxide. The combination of dielectric regions can include a silicon oxide and a dielectric nitride such as, but not limited to, a silicon nitride. Dielectric 212-1 can have the same composition as dielectric 212-2. Dielectric 212-3 can have the same composition as dielectric 212-1 or dielectric 212-2.

Gate structure 220-1 of transistor 201-1 is a conductive structure, which can comprise a single conductive material or multiple conductive material regions. Gate structure 220-1 can be a conductive polysilicon gate, a metal gate, a metal gate separated from dielectric 212-1 by one or more metal barrier regions, or, in combination with dielectric 212-1, a HKMG. The high-k dielectric of the HKMG can be located on a thin layer of silicon oxide. Material for the metal gate of gate structure 220-1 can be, but is not limited to, tungsten or ruthenium. Metal barrier regions can include, but are not limited to, one or more of tungsten silicide, tungsten nitride, titanium, titanium nitride, or titanium silicide. Other conductive materials can be used for gate structure 220-1. Gate structure 220-2 of transistor 201-2 is a conductive structure, which can comprise a single conductive material or multiple conductive material regions. Gate structure 220-2 can be a conductive polysilicon gate, a metal gate, a metal gate separated from dielectric 212-2 by one or more metal barrier regions, or, in combination with dielectric 212-2, a HKMG. The high-k dielectric of the HKMG can be located on a thin region of silicon oxide. Material for the metal gate of gate structure 220-2 can be, but is not limited to, tungsten or ruthenium. Metal barrier regions can include, but are not limited to, one or more of tungsten silicide, tungsten nitride, titanium, titanium nitride, or titanium silicide. Other conductive materials can be used for gate structure 220-2. The composition of gate structure 220-2 can be the same as the composition of gate structure 220-1.

Source region 210 has a source junction having a source junction depth of d5 from the top of source region 210 to the bottom of source region 210. Drain region 205-1 has a drain junction having a drain junction depth of d6 from the top of drain region 205-1 to the bottom of drain region 205-2. Drain region 205-2 has a drain junction having a drain junction depth of d7 from the top of drain region 205-2 to the bottom of drain region 205-2. Source junction depth d5 can be shallower than drain junction depth d6 and shallower than drain junction depth d7. By shallower, it is meant that source junction depth d5 is less than drain junction depth d6 by more than a tolerance specification for transistor 201-1 and that source junction depth d5 is less than drain junction depth d7 by more than a tolerance specification for transistor 201-2. In a typical transistor structure, the source junction depth and the drain junction depth are substantially the same. In device 200, with source junction depth d5 being shallower than drain junction depth d6 or shallower than drain junction depth d7, device 200 defines an asymmetric device. Drain junction depth d6 or drain junction depth d7 can be at least twice source junction depth d5. Drain junction depth d6 can be equal to drain junction depth d7 within tolerance levels for transistors 201-1 and 201-2.

Construction of source region 210 having a shallower source junction depth than the drain junction depth of transistor 201-1 or transistor 201-2 can be based on doping procedures for transistors 201-1 and 201-2. With standard processing, source and drain regions are doped in the same procedural stage, resulting in source junction and drain junction depths having the same depth (within process tolerance). Transistor 201-1 and transistor 201-2 can be constructed as an asymmetric device by additional doping of drain region 205-1 and drain region 205-2 while inhibiting or preventing additional doping of common source region 210, extending the drain junctions of drain region 205-1 and drain region 205-1 to depths larger than the source junction of source region 210. Arrangement of gate structure 220-1 relative to gate structure 220-2 can be used to inhibit or prevent additional doping of common source region 210. For a distance d8 of an opening between gate structure 220-1 relative to gate structure 220-2 during processing of transistors 201-1 and 201-2, the opening defined by d8 can be used in the inhibiting or preventing of additional doping of source region 210. While distance d8 is associated with inhibiting source region 210, a distance dll between gate structure 220-1 and gate structure 220-4 and a distance d12 between gate structure 220-2 and gate structure 220-3 are associated with process opening to provide additional dopants to drain regions 205-1, 205-2, 205-3, 205-4, and 205-5 for device 200. The selective additional doping of drain region 205-1 and drain region 205-2 relative to common source region 210 can be a function of distance d8 between gate structure 220-1 and gate structure 220-1 over the common source region 210 along with being a function of distances d11 and d12.

The distances d8, d11, and d12 may be further defined by dielectric sidewalls on gate structures 220-1, 220-2, 220-3, and 220-4, which sidewalls are not shown in FIG. 2. Transistor 201-3 may be one of a pair of transistors having a common source region. Transistor 201-4 may be one of another pair of transistors having a common source region. Transistor 201-3 and transistor 201-4 can be structured similar to transistor 201-1 and transistor 201-2, respectively. In various embodiments, the transistors of device 200 can include LDDs and Halo regions.

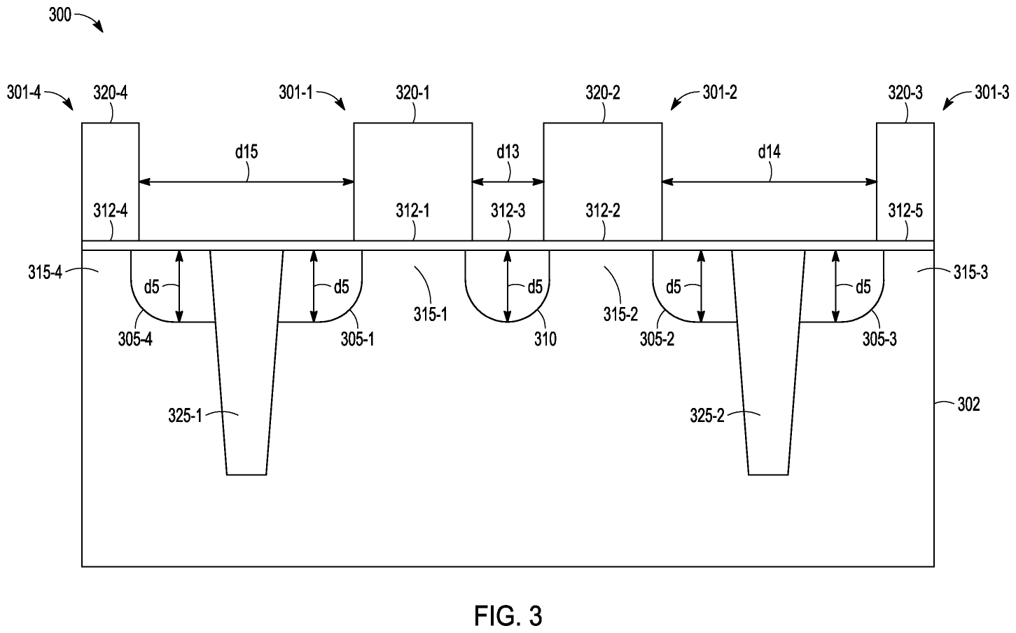

FIG. 3 shows a structure 300 after several processing stages to form a device having two transistors sharing a common source region 310. The device being formed can be similar to device 200 with a source junction depth d5. Structure 300 can be formed with a source junction depth being less than or greater than d5. At this position in the process of forming a device having one or more pairs of transistors sharing a common source, structure 300 can include a drain region 305-1 separated from source region 310 by a channel structure 315-1, where channel structure 315-1 is separated from a gate structure 320-1 by a dielectric 312-1 for a transistor 301-1. Structure 300 can include a drain region 305-2 separated from source region 310 by a channel structure 315-2, where channel structure 315-2 is separated from a gate structure 320-2 by a dielectric 312-2 for a transistor 301-2. A dielectric 312-3 can be located on source region 310. A STI region 325-1 can isolate drain region 305-1 from a drain region 305-4, where a dielectric 312-4 separates a channel structure 315-4 from a gate structure 320-4 for a transistor 301-4. A STI region 325-2 can isolate drain region 305-2 from drain region 305-3, where dielectric 312-5 separates a channel structure 315-3 from a gate structure 320-4 for a transistor 301-3.

The portions of structure 300 can be formed with materials to provide structure 300 having materials similar to device 200 of FIG. 2. The portions of structure 300 can be fabricated using one or more material removal procedures and one or more material formation processes. Conventional techniques for removing material such as masking, etching, and other removal processes can be used. Selective etching can be used to remove selected regions in the processing. Selective etching is a process in which one or more materials are removed from a structure, while one or more other materials remain in the structure with no or little removal. Selective etching can depend on the material to be etched, the material not to be etched, the etchant employed, and the method for etching. Etching procedures can include, but are not limited to, wet etching, dry etching, and atomic layer etching deposition, among others Various deposition techniques for components of structure 300 can be used that are typical for the material being formed, the dimensions of the material being formed, and the architecture in which the material is being formed. The formation techniques can use conventional techniques for forming materials in semiconductor based electronic devices. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition, and laser chemical vapor deposition, among others.

In various embodiments, similar components may be processed in common procedures. Dielectrics 312-1, 312-2, 312-3, and 314-4 can be processed on a surface to source region 310, drain regions 305-1, 305-2, 305-3, and 305-4, and substrate 302 using the same material compositions. Gate structures 320-1, 320-2, 32-3, and 320-4 can be processed in a common procedures with the same materials. Processed structure 300 can include source region 110 having a source junction depth of d5 and each of drain regions 305-1, 305-2, 305-3, and 305-4 having drain junction depths of d5. Though the source junction depth and the drain junction depths are being formed with equal depths for processed structure 300, there may be essentially negligible differences that are within processing tolerances. In various embodiments, LDDs and Halo regions can be made in structure 300. Processed structure 300 can include an opening having a distance d13 between gate structures 320-1 and 320-2, an opening having a distance d14 between gate structures 320-2 and 320-3, and an opening having a distance d15 between gate structures 320-1 and 320-4. The distances d14 and d15 can be made substantially equal. Distances d14 and d15 are made to be substantially greater than d13 for further processing.

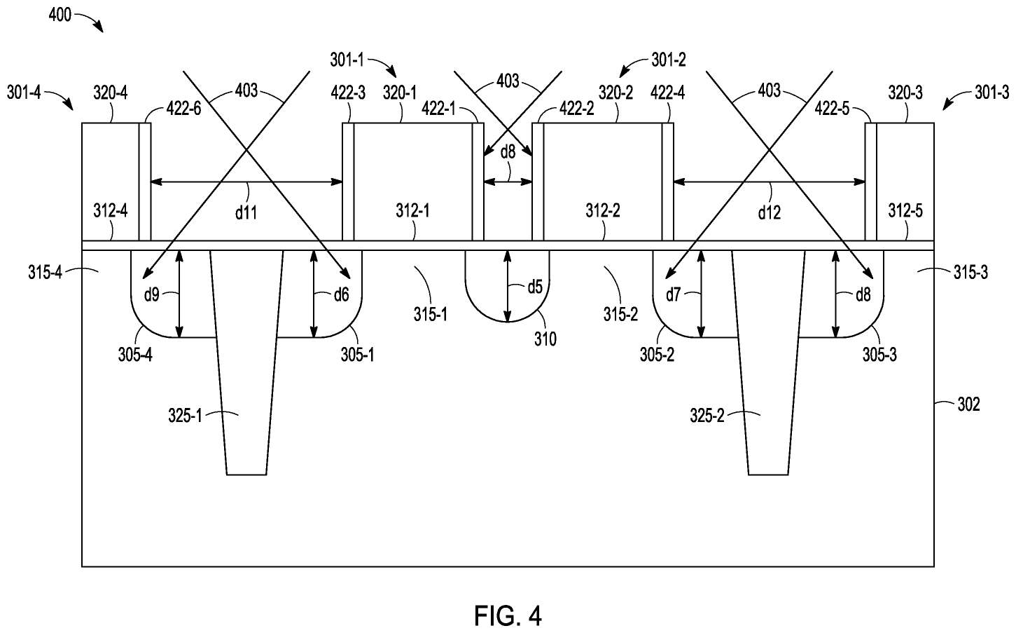

FIG. 4 shows a structure 400 after further processing structure 300 of FIG. 3 to form transistors 301-1, 301-2, 301-3, and 301-4. Sidewall 422-1 has been formed on gate structure 320-1 and sidewall 422-2 has been formed on gate structure 320-2, such that the opening defined by distance d13 in structure 300 has been reduced to an opening defined by distance d8. Sidewall 422-3 has been formed on gate structure 320-1 and sidewall 422-6 has been formed on gate structure 320-4, such that the opening defined by distance d15 in structure 300 has been reduced to an opening defined by distance d11. Sidewall 422-4 has been formed on gate structure 320-2 and sidewall 422-5 has been formed on gate structure 320-3, such that the opening defined by distance d14 in structure 300 has been reduced to an opening defined by distance d12. The openings defined by distances d8, d11, and d12 can be used to provide additional dopants to drain regions 305-1, 305-2, 305-3, and 305-4, while inhibiting or preventing additional doping of common source region 310.

FIG. 4 illustrates additional doping by an implant process in which dopants 403 are directed at an implant angle greater than or equal to a threshold angle for drain doping. The threshold angle, for this process, is defined with respect to the vertical to the surface of structure 400 as an angle resulting in components of structure 400 blocking implantation of dopants into source region 310 and at which further tilting from the vertical results in components of structure 400 blocks implantation of dopants into source region 310. At a tilted angle greater than the threshold angle, dopant implants do not follow a path to source region 310 through the opening defined by distance d8. At a tilted angle less than the threshold angle, dopant implants can follow a path to source region 310 through the opening defined by distance d8. For example, a small tilt from zero degrees results in dopants 403 directed to source region 310.

With openings defined by distances d11 and d12 being significantly greater than the opening defined by distance d8, dopants 403 can be injected into drain regions 305-1, 305-2, 305-3, and 305-4 using ion implantation, while dopants 403 are blocked from entering source region 310 by gate structures 320-1 and 320-2 and use of a tilt angle of implantation being greater than or equal to the threshold angle defined by distance d8. With distance d8 defining a threshold tilt angle, distances d11 and d12 can define a maximum tilt angle. In various embodiments, the threshold tilt angle can be about 35 degrees For an appropriate distance d8. In various embodiments, the tilt angle for injecting dopants 403 can be in a range from about twenty-five degrees to about fifty degrees. Other ranges may be used depending on the values of distances d8, d11, and d12. The additional doping of drain regions 305-1, 305-2, 305-3, and 305-4 of structure 300 of FIG. 3 can extend the drain junction depths of these drains from d5 to d6, from d5 to d7. from to d8, and from d5 to d9, respectively. The use of tilted implant angles allows for the additional doping to form asymetric structures without an additional mask to dope only on the drain side and skip doping on the source side. Without additional processing such as masking, the drain junction depths d6, d7, d8, and d9 can be equal to each other within processing tolerances. The drain junction depths d6, d7, d8, and d9 can be made constructed to be at least twice that of the source junction depth. The drain junction depths d6, d7, d8, and d9 can be selectively constructed to be greater than the source junction depth and less than twice the source junction depth. Dopants 403 for the additional doping can include materials appropriate for the conductivity type of drain regions 305-1, 305-2, 305-3, and 305-4. The implant source can use 30 keV for implantation. Other implant energies can be used such that the ion implantation can be conducted using energy sources selected to match a desired drain junction depth.

Though the processes shown in FIGS. 3 and 4 illustrate five drain regions in which two of the drain regions are associated with a common source region, the above processes can be directed to forming multiple pairs of transistors with each transistor pair having a common source region in a IC. The transistors can be formed in common procedures providing asymmetric structures with matched characteristics. Such processing of the transistors can result in transistor pairs with matched Vₜs. An implant scheme, similar to the implant scheme of FIG. 4, implant scheme can improve I_{ON} by 3%-5% for these transistors. The implant process can be used in forming a variety of electronic chips.

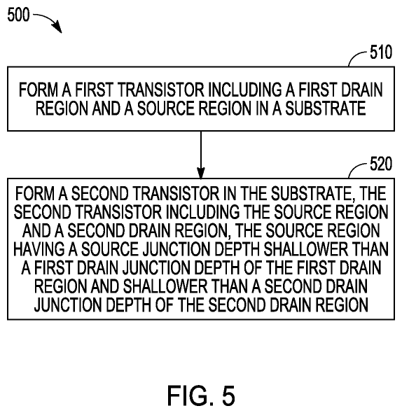

FIG. 5 is a flow diagram of features of an embodiment of an example method 500 of forming an electronic device. At 510, a first transistor is formed including a first drain region and a source region in a substrate. At 520, a second transistor is formed in the substrate, where the second transistor includes the source region and a second drain region. The source region has a source junction depth shallower than a first drain junction depth of the first drain region and shallower than a second drain junction depth of the second drain region. The first transistor and the second transistor share the same source region. The first transistor and the second transistor can be formed as either n-type transistors or p-type transistors, depending on the electronic device for which the first transistor and the second transistor are incorporated.

Variations of method 500 or methods similar to method 500 can include a number of different embodiments that may be combined depending on the application of such methods and/or the architecture of systems including an electronic device in which such methods are implemented. Such methods can include forming the source region and portions of the first drain region and portions of the second drain region prior to forming the first drain region to the first drain junction depth and prior to forming the second drain region to the second drain junction depth. Forming the first drain region to the first drain junction depth and forming the second drain region to the second drain junction depth can be performed in a common doping process. The common doping process can be conducted in a manner such that the common source region to the first transistor and the second transistor is not doped during the common doping process.

Variations of method 500 or methods similar to method 500 can include, in the formation of the first transistor and the second transistor, forming a first gate structure of the first transistor on a first dielectric, where the first dielectric extends between the source region and the first drain region. A second gate structure of the second transistor can be formed on a second dielectric, where the second dielectric extends between the source region and the second drain region. Additional dopants can be implanted into the first drain region and additional dopants can be implanted into the second drain region at a tilt angle such that the first gate structure and the second gate structure block implanting additional dopants into the source region. The tilt angle can be a function of a distance between the first gate structure and the second gate structure. The tilt angle can be in a range from about twenty-five degrees to about fifty degrees. Other tilt angles can be used.

Variations of method 500 or methods similar to method 500 can include forming a first gate structure for the first transistor, where the first gate structure has a first height, forming a second gate structure for the second transistor, where the second gate structure has a second height, and doping the first drain region and the second drain region with additional doping. The first gate structure and the second gate structure blocks the doping of the source region during the doping of the first drain region and the second drain region with additional doping. Variations can include forming the second drain junction depth being at least twice the source junction depth. The first drain junction depth can be formed being at least twice the source junction depth. Variations can include forming the first transistor having a threshold voltage matched to a threshold voltage of the second transistor.

In various embodiments, an electronic device can comprise a first transistor including a first drain region and a source region and a second transistor including the source region and a second drain region. The source region can have a source junction depth shallower than a first drain junction depth of the first drain region and shallower than a second drain junction depth of the second drain region. The electronic device can be implemented in a number of different systems having an architecture in which one or more pairs of transistor share a common source region. The electronic device can be a memory die, a packaged memory device, or a packaged memory device having multiple memory dies.

Variations of such an electronic device and its features, as taught herein, can include a number of different embodiments and features that can be combined depending on the application of such electronic devices, the format of such electronic devices, and/or the architecture in which such electronic devices are implemented. Variations of such electronic devices can include the first drain junction depth being at least twice the source junction depth. Variations of such an electronic device can include a p-type substrate in which the first drain region, the second drain region, and the source region are disposed, with the first drain region being a n-type region, the second drain region being a n-type region, and the source region being a n-type region. Variations of such an electronic device can include the first transistor and the second transistor being p-type transistors. Variations of such an electronic device can include the first drain region being separated from a third drain region of a third transistor by a first isolation region and the second drain region being separated from a fourth drain region of a fourth transistor by a second isolation region.

Variations of such an electronic device and its features can include the first transistor having a first gate structure with a first height and the second transistor having a second gate structure with a second height. The first height and the second height can be implemented such that, in fabrication, the first gate structure and second gate structure block doping of the common source region during additional doping of the first and second drain regions. The doping can be accomplished using a tilted implant of dopants. Variations of such an electronic device can include a tilt angle of the tilted implant being a function of a distance between the first gate structure and the second gate structure over the source region. Variations of such an electronic device can include the first transistor having a threshold voltage matched to a threshold voltage of the second transistor.

In various embodiments, a system can comprise a memory device having a memory cell array coupled to a SA. The SA can have a first transistor including a first drain region and a source region and a second transistor including the source region and a second drain region. The source region can have a source junction depth shallower than a first drain junction depth of the first drain region and shallower than a second drain junction depth of the second drain region.

Variations of such a system and its features, as taught herein, can include a number of different embodiments and features that can be combined depending on the application of such systems, the format of such systems, and/or the architecture in which such systems are implemented. Variations of such systems can include the first drain junction depth being at least twice the source junction depth. Variations of such a system can include the first transistor having a first gate structure with a first height and the second transistor having a second gate structure with a second height such that, in fabrication, the first gate structure and the second gate structure block doping of the source region during additional doping of the first and second drain regions using a tilted implant. A tilt angle of the tilted implant can be a function of a distance between the first gate structure and the second gate structure over the source region. Variations of such a system can include the SA being a PSA. Variations of such a system can include the SA being a NSA.

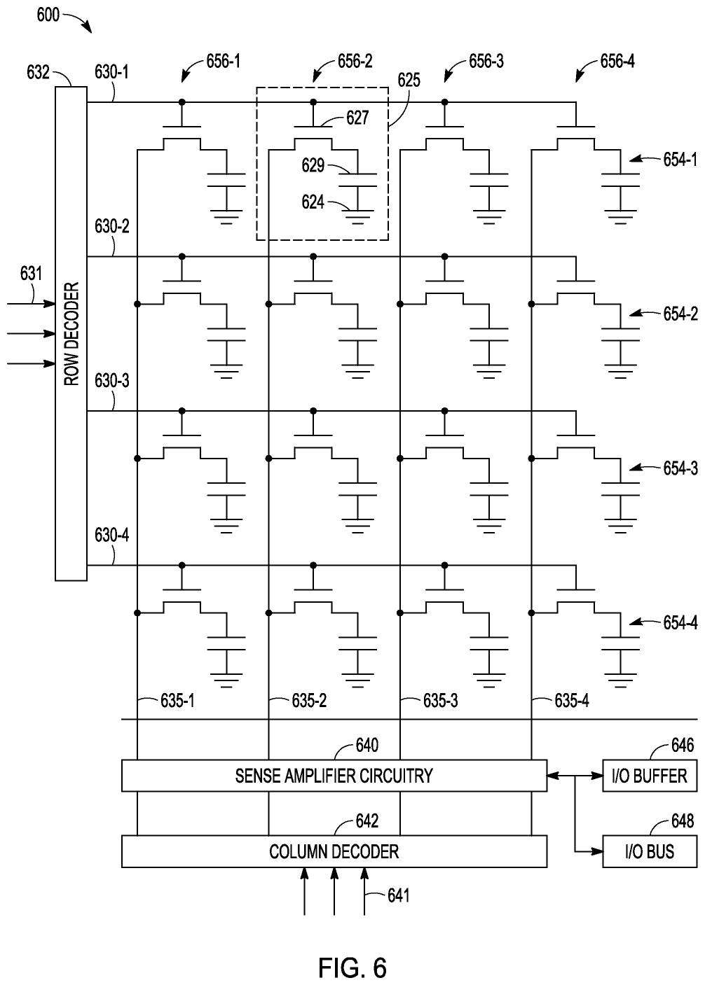

FIG. 6 is a schematic of an embodiment of an example DRAM device 600 that can include an architecture having a memory array region and periphery circuits to the memory array, in which the periphery circuits can have asymmetric transistor devices as discussed herein with respect to FIGS. 1-5. DRAM device 600 can include an array of memory cells 625 (only one being labeled in FIG. 6 for case of presentation) arranged in rows 654-1, 654-2, 654-3, and 654-4 and columns 656-1, 656-2, 656-3, and 656-4. For simplicity and case of discussion, the array is shown in only two dimensions, but the array can be extended into the third dimension. Further, while only four rows 654-1, 654-2, 654-3, and 654-4 and four columns 656-1, 656-2, 656-3, and 656-4 of four memory cells are illustrated, DRAM devices, like DRAM device 600, can have significantly more memory cells 625 (e.g., tens, hundreds, or thousands of memory cells) per row or per column.

Each memory cell 625 can include a single transistor 627 and a single capacitor 629, which is commonly referred to as a ITIC (one-transistor-one capacitor cell). One plate of capacitor 629, which can be termed the “node plate,” is connected to the drain terminal of transistor 627, whereas the other plate of the capacitor 629 is connected to ground 624 or other reference node. Each capacitor 629 within the array of ITIC memory cells 625 typically serves to store one bit of data, and the respective transistor 627 serves as an access device to write to or read from storage capacitor 629.

The transistor gate terminals within each row of rows 654-1, 654-2, 654-3, and 654-4 are portions of respective access lines 630-1, 630-2, 630-3, and 630-4 (alternatively referred to as “word lines”), and the transistor source terminals within each of columns 656-1, 656-2, 656-3, and 656-4 are electrically connected to respective digit lines 635-1, 635-2, 635-3, and 635-4 (alternatively referred to as “bit lines”). A row decoder 632 can selectively drive the individual access lines 630-1, 630-2, 630-3, and 630-4, responsive to row address signals 631 input to row decoder 632. Driving a given access line at a high voltage causes the access transistors within the respective row to conduct, thereby connecting the storage capacitors within the row to the respective data lines, such that charge can be transferred between the data lines and the storage capacitors for read or write operations. Both read and write operations can be performed via sense amplifier (SA) circuitry 640, which can transfer bit values between the memory cells 625 of the selected row of the rows 654-1, 654-2, 654-3, and 654-4 and input/output buffers 646 (for write/read operations) or external input/output data buses 648.

SA circuitry 640 can include multiple pairs of transistors, where each transistor pair of the set of multiple pairs shares a common source region. Each pair provides an asymmetric transmitter device with the common source region having a source junction depth that is shallower than the drain junction depths of the drain regions of the pair of transistors. Such an asymmetric junction scheme can be used to control the threshold voltage (Vₜ) of the transistor devices of sense amplifier circuitry 640 through the common source region that is the source side of transistors. The transistors of the pairs can have characteristics that provide for matched Vₜs, which can provide enhance I_{ON} and I_{OFF} characteristics of the transistors of SA circuitry 640. Depending on the architecture of DRAM device 600, SA circuitry 640 can include an asymmetric NSA or an asymmetric PSA, as taught herein.

A column decoder 642 responsive to column address signals 641 can select which of the memory cells 625 within the selected row is read out or written to. Alternatively, for read operations, the storage capacitors 629 within the selected row can be read out simultaneously and latched, and the column decoder 642 can then select which latch bits to connect to the output data bus 648. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 600 can be implemented as an integrated circuit within a package that includes pins for receiving supply voltages (e.g., to provide the source and gate voltages for the transistors 627) and signals (including data, address, and control signals). FIG. 6 depicts DRAM device 600 in simplified form to illustrate basic structural components, omitting many details of the memory cells 625 and associated access lines 630-1, 630-2, 630-3, and 630-4 and digit lines 635-1, 635-2, 635-3, and 635-4 as well as the peripheral circuitry. For example, in addition to the row decoder 632 and column decoder 642, SA circuitry 640, and buffers 646, DRAM device 600 can include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

In two-dimensional (2D) DRAM arrays, the rows 654-1, 654-2, 654-3, and 654-4 and columns 656-1, 656-2, 656-3, and 656-4 of memory cells 625 are arranged along a single horizontal plane (i.e.., a plane parallel to the layers) of the semiconductor substrate, e.g., in a rectangular lattice with mutually perpendicular horizontal access lines 630-1, 630-2, 630-3, and 630-4 and digit lines 635-1, 635-2, 635-3, and 635-4. In 3D DRAM arrays, the memory cells 625 are arranged in a 3D lattice that encompasses multiple vertically stacked horizontal planes corresponding to multiple device tiers of a multi-tier substrate assembly, with each device tier including multiple parallel rows of memory cells 625 whose transistor gate terminals are connected by horizontal access lines such as access lines 630-1, 630-2, 630-3, and 630-4. (A “device tier,” as used herein, can include multiple layers (or levels) of materials, but forms the components of memory devices of a single horizontal tier of memory cells.) Digit lines 635-1, 635-2, 635-3, and 635-4 extend vertically through all or at least a vertical portion of the multi-tier structure, and each of the digit lines 635-1, 635-2, 635-3, and 635-4 connects to the transistor source terminals of respective vertical columns 656-1, 656-2, 656-3, and 656-4 of associated memory cells 625 at the multiple device tiers. This 3D configuration of memory cells enables further increases in bit density compared with 2D arrays.

Though FIG. 6 provides an example of DRAM device 600 that can include asymmetric transistor devices as discussed with respect to FIGS. 1-5, other ICs can implement similar asymmetric transistor devices that can be used in a variety of electronic devices. Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include asymmetric transistor devices within the electronic devices.

The following examples are example embodiments of methods, devices, and systems, in accordance with the teachings herein.

An example electronic device 1 can comprise a first transistor including a first drain region and a source region and a second transistor including the source region and a second drain region. The source region has a source junction depth shallower than a first drain junction depth of the first drain region and shallower than a second drain junction depth of the second drain region.

An example electronic device 2 can include features of example electronic device 1 and can include the first drain junction depth being at least twice the source junction depth.

An example electronic device 3 can include features of any features of the preceding example electronic devices and can include a p-type substrate in which the first drain region, the second drain region, and the source region are disposed, with the first drain region being a n-type region, the second drain region being a n-type region, and the source region being a n-type region.

An example electronic device 4 can include features of any of the preceding example electronic devices and can include the first drain region being separated from a third drain region of a third transistor by a first isolation region and the second drain region being separated from a fourth drain region of a fourth transistor by a second isolation region.

An example electronic device 5 can include features of any of the preceding example electronic devices and can include the first transistor having a first gate structure having a first height and the second transistor having a second gate structure having a second height such that, in fabrication, the first gate structure and second gate structure block doping of the source region during additional doping of the first and second drain regions using a tilted implant.

An example electronic device 6 can include features of example electronic device 5 and any of the preceding example electronic devices and can include a tilt angle of the tilted implant being a function of a distance between the first gate structure and the second gate structure over the source region.

An example electronic device 7 can include features of any of the preceding example electronic devices and can include the first transistor having a threshold voltage matched to a threshold voltage of the second transistor.

In an example electronic device 8, any of the electronic devices of example electronic devices 1 to 7 may include incorporation into an electronic apparatus further comprising a host processor and a communication bus extending between the host processor and the electronic device.

In an example electronic device 9, any of the electronic devices of example electronic devices 1 to 9 may be modified to include any structure presented in another of example electronic device 1 to 9.

In an example electronic device 10, any apparatus associated with the electronic devices of example electronic devices 1 to 9 may further include a machine-readable storage device configured to store instructions as a physical state, wherein the instructions may be used to perform one or more operations of the apparatus.

In an example electronic device 11, any of the electronic devices of example electronic devices 1 to 9 may be operated in accordance with any of the below example methods 1 to 12.

An example system 1 can comprise a memory device having a memory cell array coupled to a sense amplifier, where the sense amplifier has a first transistor including a first drain region and a source region and a second transistor including the source region and a second drain region. The source region has a source junction depth shallower than a first drain junction depth of the first drain region and shallower than a second drain junction depth of the second drain region.

An example system 2 can include features of preceding example system 1 and can include the first drain junction depth being at least twice the source junction depth.

An example system 3 can include features of any of the preceding example systems and can include the first transistor having a first gate structure having a first height and the second transistor having a second gate structure having a second height such that, in fabrication, the first gate structure and the second gate structure block doping of the source region during additional doping of the first and second drain regions using a tilted implant.

An example system 4 can include features of example system 3 and any of the preceding example systems and can include a tilt angle of the tilted implant being a function of a distance between the first gate structure and the second gate structure over the source region.

An example system 5 can include features of any features of the preceding example systems and can include the sense amplifier being a p-type sense amplifier.

In an example system 6, any of the systems of example systems 1 to 5 may include one or more systems incorporated into an electronic apparatus further comprising a host processor and a communication bus extending between the host processor and the one or more systems.

In an example system 7, any of the systems of example systems 1 to 6 may be modified to include any structure presented in another of example systems 1 to 6.

In an example system 8, any apparatus associated with the systems of example systems 1 to 7 may further include a machine-readable storage device configured to store instructions as a physical state, wherein the instructions may be used to perform one or more operations of the apparatus.

In an example system 9, any of the systems of example systems 1 to 8 may be operated in accordance with any of the methods of the below example methods 1 to 12.

An example method 1 of forming an electronic device can comprise forming a first transistor including a first drain region and a source region in a substrate and forming a second transistor in the substrate. Forming the second transistor can include forming the second transistor to include the source region and a second drain region. The source region can be formed having a source junction depth shallower than a first drain junction depth of the first drain region and shallower than a second drain junction depth of the second drain region.

An example method 2 of forming an electronic device can include features of example method 1 of forming an electronic device and can include forming the source region and portions of the first drain region and portions of the second drain region prior to forming the first drain region to the first drain junction depth and prior to forming the second drain region to the second drain junction depth.

An example method 3 of forming an electronic device can include features of any of the preceding example methods of forming an electronic device and can include forming a first gate structure of the first transistor on a first dielectric, the first dielectric extending between the source region and the first drain region; forming a second gate structure of the second transistor on a second dielectric, the second dielectric extending between the source region and the second drain region; and implanting additional dopants into the first drain region and additional dopants into the second drain region at a tilt angle such that the first gate structure and the second gate structure block implanting additional dopants into the source region.

An example method 4 of forming an electronic device can include features of example method 3 of forming an electronic device and any of the preceding example methods of forming an electronic device and can include the tilt angle being a function of a distance between the first gate structure and the second gate structure.

An example method 5 of forming an electronic device can include features of any of the preceding example methods of forming an electronic device and can include the tilt angle being in a range from about twenty-five degrees to about fifty degrees.

An example method 6 of forming an electronic device can include features of any of the preceding example methods of forming an electronic device and can include forming the first transistor having a threshold voltage matched to a threshold voltage of the second transistor.

An example method 7 of forming an electronic device can include features of any of the preceding example methods of forming an electronic device and can include forming a first gate structure for the first transistor, the first gate structure having a first height; forming a second gate structure for the second transistor, the second gate structure having a second height; and doping the first drain region and the second drain region with additional doping, with the first gate structure and the second gate structure blocking doping of the source region during the doping of the first drain region and the second drain region with additional doping.

An example method 8 of forming an electronic device can include features of any of the preceding example methods of forming an electronic device and can include forming the second drain junction depth being at least twice the source junction depth.

In an example method 9 of forming an electronic device, any of the example methods 1 to 8 of forming an electronic device may be performed in forming an electronic apparatus further comprising a host processor and a communication bus extending between the host processor and the memory device.

In an example method 10 of forming an electronic device, any of the example methods 1 to 9 of forming an electronic device may be modified to include operations set forth in any other of example methods 1 to 9 of forming an electronic device.

In an example method 11 of forming an electronic device, any of the example methods 1 to 10 of forming an electronic device may be implemented at least in part through use of instructions stored as a physical state in one or more machine-readable storage devices.

An example method 12 of forming an electronic device can include features of any of the preceding example methods 1 to 11 of forming an electronic device and can include performing functions associated with any features of example electronic devices 1 to 11 and example systems 1 to 9.

An example machine-readable storage device 1 storing instructions, that when executed by one or more processors, cause a machine to perform operations, can comprise instructions to perform functions associated with any features of example electronic devices 1 to 11 and example systems 1 to 9 or perform methods associated with any features of example methods of forming an electronic device 1 to 12.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An electronic device comprising:
a first transistor including a first drain region and a source region; and
a second transistor including the source region and a second drain region, the source region having a source junction depth shallower than a first drain junction depth of the first drain region and shallower than a second drain junction depth of the second drain region.

2. The electronic device of claim 1, wherein the first drain junction depth is at least twice the source junction depth.

3. The electronic device of claim 1, wherein the electronic device includes a p-type substrate in which the first drain region, the second drain region, and the source region are disposed, with the first drain region being a n-type region, the second drain region being a n-type region, and the source region being a n-type region.

4. The electronic device of claim 1, wherein the first drain region is separated from a third drain region of a third transistor by a first isolation region and the second drain region is separated from a fourth drain region of a fourth transistor by a second isolation region.

5. The electronic device of claim 1, wherein the first transistor has a first gate structure having a first height and the second transistor has a second gate structure having a second height such that, in fabrication, the first gate structure and second gate structure block doping of the source region during additional doping of the first and second drain regions using a tilted implant.

6. The electronic device of claim 5, wherein a tilt angle of the tilted implant is a function of a distance between the first gate structure and the second gate structure over the source region.

7. The electronic device of claim 1, wherein the first transistor has a threshold voltage matched to a threshold voltage of the second transistor.

8. A system comprising:
a memory device having a memory cell array coupled to a sense amplifier, the sense amplifier having:
a first transistor including a first drain region and a source region; and
a second transistor including the source region and a second drain region, the source region having a source junction depth shallower than a first drain junction depth of the first drain region and shallower than a second drain junction depth of the second drain region.

9. The system of claim 8, wherein the first drain junction depth is at least twice the source junction depth.

10. The system of claim 8, wherein the first transistor has a first gate structure having a first height and the second transistor has a second gate structure having a second height such that, in fabrication, the first gate structure and the second gate structure block doping of the source region during additional doping of the first and second drain regions using a tilted implant.

11. The system of claim 10, wherein a tilt angle of the tilted implant is a function of a distance between the first gate structure and the second gate structure over the source region.

12. The system of claim 8, wherein the sense amplifier is a p-type sense amplifier.

13. A method of forming an electronic device, the method comprising:
forming a first transistor including a first drain region and a source region in a substrate; and
forming a second transistor in the substrate, the second transistor including the source region and a second drain region, the source region having a source junction depth shallower than a first drain junction depth of the first drain region and shallower than a second drain junction depth of the second drain region.

14. The method of claim 13, wherein the method includes forming the source region and portions of the first drain region and portions of the second drain region prior to forming the first drain region to the first drain junction depth and prior to forming the second drain region to the second drain junction depth.

15. The method of claim 13, wherein the method includes:
forming a first gate structure of the first transistor on a first dielectric, the first dielectric extending between the source region and the first drain region;
forming a second gate structure of the second transistor on a second dielectric, the second dielectric extending between the source region and the second drain region; and
implanting additional dopants into the first drain region and additional dopants into the second drain region at a tilt angle such that the first gate structure and the second gate structure block implanting additional dopants into the source region.

16. The method of claim 15, wherein the tilt angle is a function of a distance between the first gate structure and the second gate structure.

17. The method of claim 15, wherein the tilt angle is in a range from about twenty-five degrees to about fifty degrees.

18. The method of claim 13, wherein the method includes forming the first transistor having a threshold voltage matched to a threshold voltage of the second transistor.

19. The method of claim 13, wherein the method includes:
forming a first gate structure for the first transistor, the first gate structure having a first height;
forming a second gate structure for the second transistor, the second gate structure having a second height; and
doping the first drain region and the second drain region with additional doping, with the first gate structure and the second gate structure blocking doping of the source region during the doping of the first drain region and the second drain region with additional doping.

20. The method of claim 13, wherein the method includes forming the second drain junction depth being at least twice the source junction depth.
